(19) United States
(12) Patent Application Publication
(10) Pub. No.: US 2010/0259287 A1
(43) Pub. Date: Oct. 14, 2010

(54) SEMICONDUCTOR TEST EQUIPMENT

(75) Inventor: Kazuaki Nakai, Osaka (JP)

Correspondence Address: MCDERMOTT WILL & EMERY LLP, 600 13TH STREET, NW, WASHINGTON, DC, 20005-3096, US

(73) Assignee: KOWA COMPANY LTD., AIRCH (JP)

(21) Appl. No.: 12/159,354

(22) PCT Filed: Jun. 20, 2007
(86) PCT No.: PCT/JP2007/062433

§ 371 Date: Sep. 19, 2008

(30) Foreign Application Priority Data
Mar. 31, 2006 (JP) 2006-096334

(51) Int. Cl. G01R 31/02; G01R 31/26

(52) U.S. Cl. 324/754; 324/765

(57) ABSTRACT

A test head (3) has test electrodes (5) for electrical connection between a test unit (4) and interface board terminals (6). The state of electrical connection of the test electrodes (5) to the interface board terminals (6) is arbitrarily controlled using respective movable parts of the test electrodes (5), whereby the state of electrical connection between the test unit (4) and the interface board terminals (6) is changed.

### RELATED APPLICATIONS

This application is the U.S. National Phase under 35 U.S.C. §371 of International Application No. PCT/JP2007/062433, filed on Jun. 20, 2007, which in turn claims the benefit of Japanese Application No. 2006-315622, filed on Nov. 22, 2006, the disclosures of which Applications are incorporated by reference herein.

### TECHNICAL FIELD

The present invention relates to semiconductor test equipment for conducting various measurements on a semiconductor integrated circuit as a device under test.

### BACKGROUND ART

In semiconductor test equipment, a test head is mounted with an interface board for transferring signals necessary for testing between a device under test and a test unit.

Test equipment for an electronic circuit device according to a conventional technique adopts a movable structure which uses bimetal for a probe that is mounted on a board such that the probe can come in contact with chip electrodes on a wafer under test in order to prevent, for example, possible damages to the chip electrodes (see Patent Document 1).

Patent Document 1: Japanese Laid-Open Patent Publication No. 2002-313855

### DISCLOSURE OF INVENTION

### Problems to be Solved by the Invention

The trend in recent years is that higher integration of the semiconductor integrated circuit leads to the increase in the area of a semiconductor integrated circuit as well as the increase in the number of device terminals. Another trend is that test cost reduction is realized by a parallel test of a plurality of semiconductor integrated circuits. However, the number of test units available is limited. In order to carry out a necessary test with the limited number of test units, a plurality of device terminals need to be connected to a specific test unit such that the connection state can be switched according to the property to be tested.

Multiple functions that the device terminal has enable, for example, one device terminal to output both digital and analog signals. The functions of the device terminal are switched as necessary. To this end, it is necessary to assign a plurality of test units to a specific device terminal of a semiconductor integrated circuit so that the connection state is switched according to the property to be tested.

However, various problems arise if the state of electric connection between the test unit and the device terminal is switched by a relay provided in the middle of the interconnection and provided on the interface board. For example, when the number of relays is increased, it is difficult to provide the relays on the interface board. Further, the wiring structure on the interface board becomes complicated due to the increase in the number of relays and provision of the relays on the interface board. As a result, test costs increase. Furthermore, the electric characteristics deteriorate because of the relay provided in the middle of the interconnection between the test unit and the device terminal.

An object of the present invention is to provide an easily changeable state of electric connection between the test unit and the interface board.

### Means For Solving The Problems

To solve the above problems, semiconductor test equipment of the present invention changes the state of electric connection between a test unit and an interface board by arbitrarily controlling the state of electric connection between the interface board and test electrodes, which electrically connect a test head and the interface board, using a movable part of each test electrode.

### Effects of the Invention

Semiconductor test equipment of the present invention does not require a relay on the interface board. In this structure, it is easier to connect a plurality of device terminals to a specific test unit of a test head, or assign a plurality of test units to a specific device terminal such that the test units are switched according to the property to be tested.

Further, since it is not necessary to provide a relay on the interface board, the wiring structure on the interface board is simplified compared to an interface board having a relay. It is therefore possible to reduce test costs. Moreover, since it is not necessary to provide a relay to the wiring connecting a test unit and a device terminal, deterioration of electric characteristics can be avoided.

### BRIEF DESCRIPTION OF DRAWINGS

FIG. 1 is a general side view of semiconductor test equipment according to the first embodiment of the present invention.

FIG. 2 is an enlarged perspective view of a test electrode of FIG. 1 in the disconnected state.

FIG. 3 is an enlarged perspective view of a test electrode of FIG. 1 in the connected state.

FIG. 4 is a general side view of semiconductor test equipment according to the second embodiment of the present invention.

FIG. 5 is an enlarged plan view of a test electrode of semiconductor test equipment according to the third embodiment of the present invention.

FIG. 6 is an enlarged perspective view of the test electrode of FIG. 5 in the disconnected state.

FIG. 7 is an enlarged perspective view of the test electrode of FIG. 5 in a connected state.

FIG. 8 is an enlarged perspective view of the test electrode of FIG. 5 in another connected state.

FIG. 9 is a cross sectional view showing the contact between the interface board and the test electrode in the state of FIG. 7.

FIG. 10 is a cross sectional view showing the contact between the interface board and the test electrode in the state of FIG. 8.

### DESCRIPTION OF REFERENCE NUMERALS

1 device terminal

2 device under test

3 test head

4 test unit

5 test electrode

6 interface board terminal

8 fixed part

9 movable part

10-14 movable part

15 insulating support bar

16 interface board

### BEST MODE FOR CARRYING OUT THE INVENTION

Embodiments of the present invention will hereinafter be described in detail based on the drawings.

<<First Embodiment>>

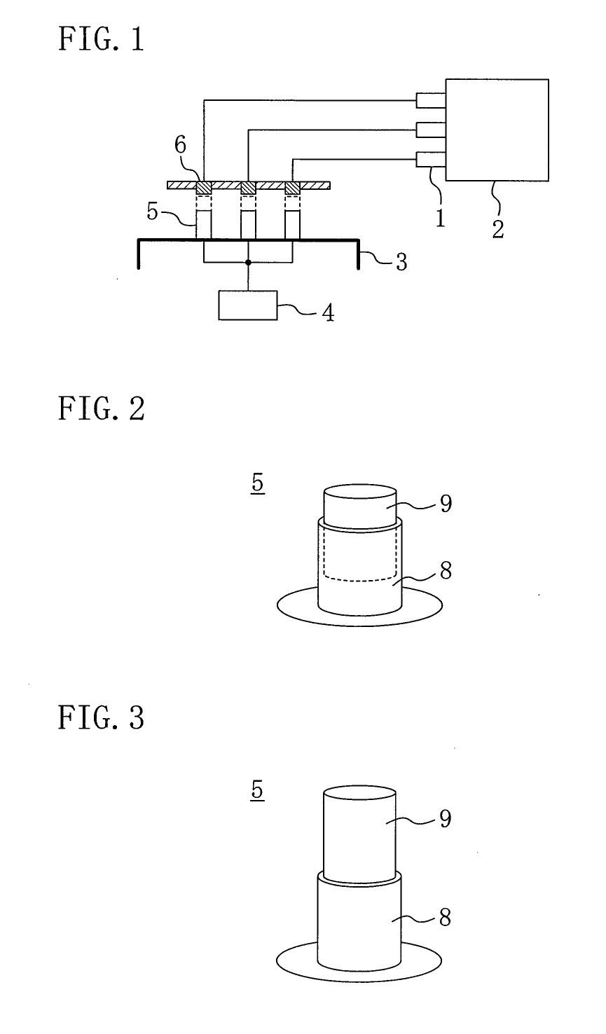

The first embodiment of semiconductor test equipment of the present invention is described. FIG. 1 through FIG. 3 show the structure of semiconductor test equipment of the first embodiment. Reference numeral 1 denotes device terminals; 2 denotes a device under test; 3 denotes a test head, 4 denotes a test unit (a channel, power supply, a signal unit, or the like); 5 denotes test electrodes (POGO pins); and 6 denotes interface board terminals. FIG. 2 is an enlarged perspective view of one of the test electrodes 5 in the disconnected state, including a fixed part 8 and a movable part 9. FIG. 3 is an enlarged perspective view of one of the test electrodes 5 in the connected state.

The semiconductor test equipment of this embodiment is characterized in that the state of connection between the test electrodes 5 and the interface board terminals 6 is switched by shifting the form of the test electrodes 5 as shown in FIG. 2 and FIG. 3 to change the state of electric connection.

The test head 3 has a plurality of test electrodes 5 to which a specific test unit 4 is electrically connected in the test head 3. Each of the test electrodes 5 is connectable to a device terminal 1. The test electrode 5 is physically moved as in FIG. 2 and FIG. 3, whereby selection of the device terminal 1 is carried out.

When the test electrode 5 is not connected to the interface board terminal 6, the movable part 9 is located inside the fixed part 8 as shown in FIG. 2, and no electric signal is sent to the device under test 2. When the test electrode 5 is connected to the interface board terminal 6, the movable part 9 is in contact with the interface board terminal 6 to establish electric connection and allow signal propagation (see FIG. 3). Means for shifting the form of the test electrode 5 as shown in FIG. 2 and FIG. 3 is not limited but may be a spring, application of an electric field, application of a magnetic field, etc.

The above-described features of the first embodiment provide a test system including one test unit 4 and a plurality of device terminals 1 connected thereto with no relay on an interface board wherein the connection path between the test unit 4 and the device terminals 1 is arbitrarily controlled for each of the test electrodes 5.

<<Second Embodiment>>

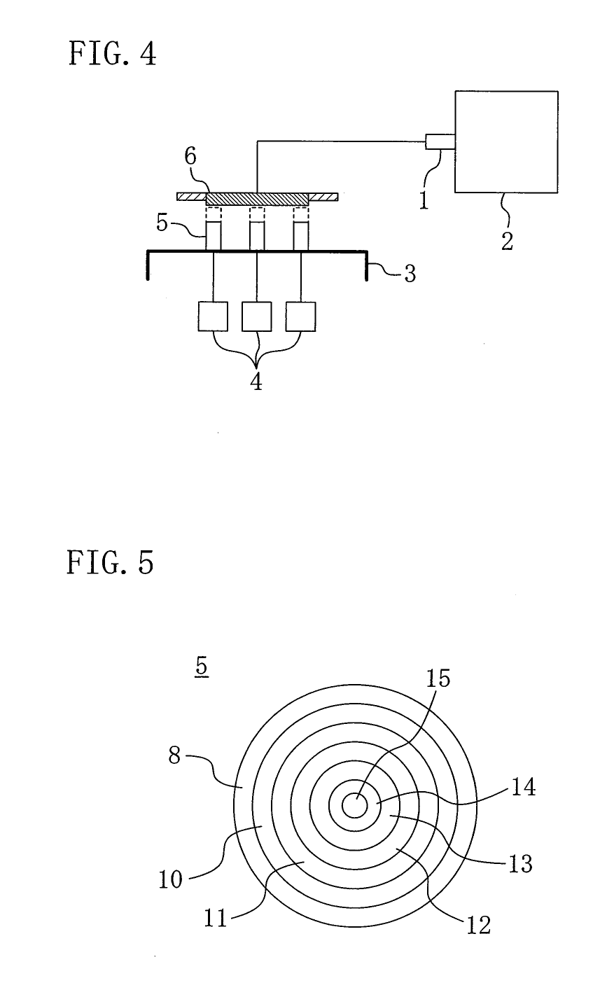

The second embodiment of semiconductor test equipment of the present invention is described. FIG. 4 shows the structure of semiconductor test equipment of the second embodiment. Reference numeral 1 denotes a device terminal; 2 denotes a device under test; 3 denotes a test head; 4 denotes test units; 5 denotes test electrodes; and 6 denotes an interface board terminal.

The semiconductor test equipment of this embodiment, too, is characterized in that the state of connection between the test electrodes 5 and the interface board terminal 6 is switched by shifting the form of the test electrodes 5 as shown in FIG. 2 and FIG. 3 to change the state of electric connection.

The test head 3 has a plurality of test electrodes 5 to which a plurality of test units 4 are electrically and independently connected in the test head 3. Each of the test electrodes 5 is connectable to a specific device terminal 1. The test electrode 5 is physically moved as in FIG. 2 and FIG. 3, whereby selection of the test unit 4 to be electrically connected to the specific device terminal 1 is carried out from among the plurality of test units 4 in the test head 3.

The above-described features of the second embodiment provide a test system including one device terminal 1 and a plurality of test units 4 connected thereto with no relay on an interface board wherein the connection path between the device terminal 1 and the test units 4 is arbitrarily controlled for each of the test electrodes 5.

<<Third Embodiment>>

The third embodiment of semiconductor test equipment of the present invention is described. FIG. 5 through FIG. 10 show the structure of a test electrode 5 and an interface board 16 of semiconductor test equipment according to the third embodiment of the present invention. The test electrode 5 includes a fixed part 8, concentric cylindrical movable parts 10 to 14, and an insulating support bar 15. The interface board 16 is adapted to the cylindrical test electrode 5.

This embodiment provides a method of connecting the test electrode 5 to the interface board 16 more securely and accurately.

As for the test electrodes 5 described in the first and second embodiments, one test electrode 5 has only one connection path. Hence, in the case where a plurality of device terminals 1 are connected to a specific test unit 4 as described in the first embodiment or in the case where a plurality of test units 4 are assigned to a specific device terminal 1 and the test units 4 are switched according to the property to be tested as described in the second embodiment, a plurality of connection paths are necessary, and accordingly, the number of the test electrodes 5 necessary is equal to the number of connection paths. In addition, in the structures of the first and second embodiments where the form of the test electrodes 5 is shifted as shown in FIG. 2 and FIG. 3 so that the state of electric connection of each test electrode 5 is switched, the physical relationship between the test electrode 5 and the interface board terminal 6 cannot be checked, and therefore, it is uncertain whether a desired state of connection is achieved.

In view of such, semiconductor test equipment of the third embodiment is characterized in that a test electrode 5 for electrical connection between one or more test units 4 and an interface board 16 has a plurality of cylindrical movable parts that are combined together, the movable parts 10 to 14 being independently operable to change the state of electric connection between the test units 4 and the interface board 16. Tests are carried out by combining the test electrode 5 with an interface board 16 adapted to the test electrode 5.

The test electrode 5 has a cylindrical structure as shown in FIG. 5 through FIG. 8 and, specifically, is formed by combining the first to fifth movable parts 10 to 14 that have different radii. These movable parts 10 to 14 are insulated from each other and, namely, not electrically connected with each other.

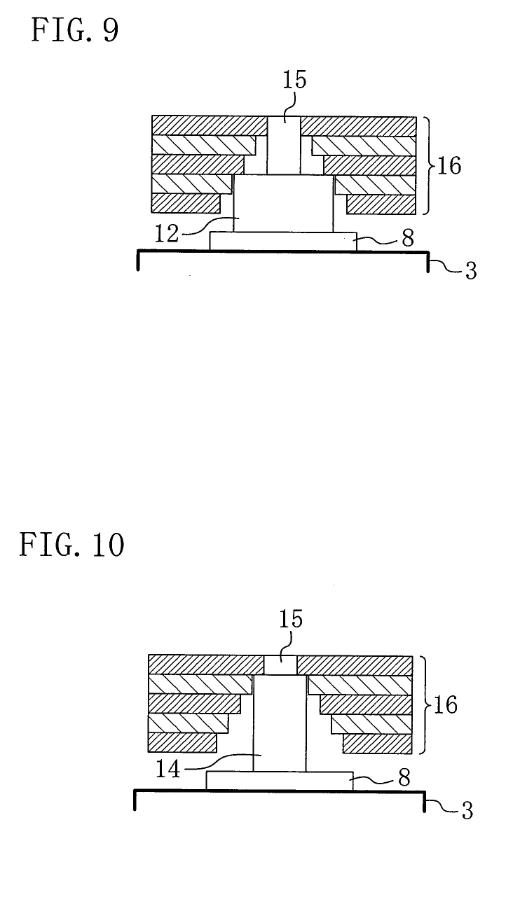

FIG. 9 and FIG. 10 show a structure of an interface board 16 adapted to the test electrode 5 having the structure shown in FIG. 5 through FIG. 8. The terminal portion of the interface board 16 has a conical structure. This terminal portion of the interface board 16 is composed of a plurality of layers each having an independent terminal. The terminals of the layers are electrically insulated from one another.

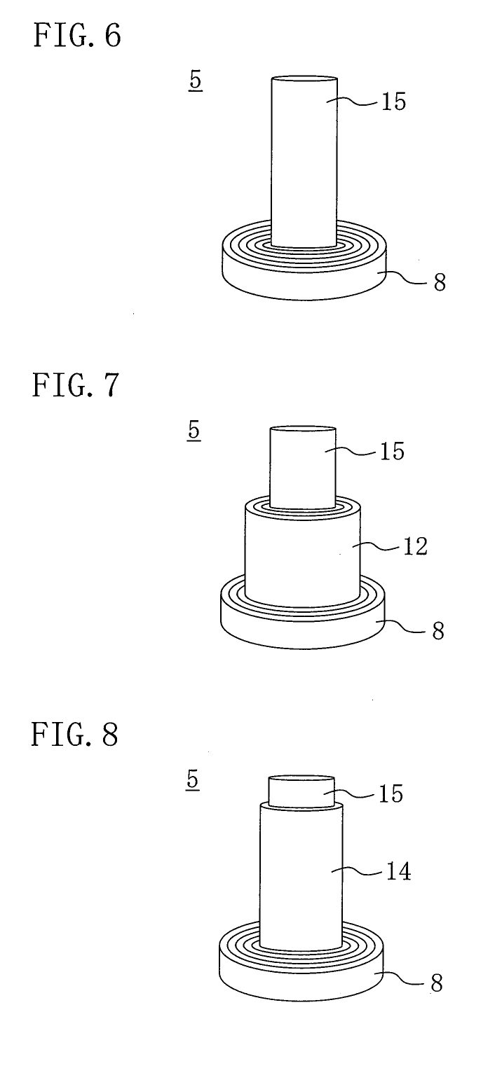

When the test electrode 5 is not used for a test, all the movable parts 10 to 14 are located inside the fixed part 8 by which the test electrode 5 is mounted on the test head 3 as shown in FIG. 6. In the case where the third movable part 12 is used, the third movable part 12 is moved upward as shown in FIG. 7, so that the third movable part 12 connects to the terminal of a specific layer of the interface board 16 (third layer from the bottom) as shown in FIG. 9, and allows propagation of an electric signal to the device under test 2. In the case where the fifth movable part 14 is used, the fifth movable part 14 is moved upward as shown in FIG. 8, so that the fifth movable part 14 connects, as shown in FIG. 10, to the terminal of a specific layer of the interface board 16 (the uppermost layer) which is different from the connected layer of FIG. 9 and allows propagation of an electric signal to the device under test 2.

In this structure, it is possible to form a plurality of connection paths by one test electrode 5 that is composed of a set of combined parts. Accordingly, it is possible to suppress the increase in the number of electrodes in such structures that a plurality of device terminals 1 are connected to a specific test unit 4 and that a plurality of test units 4 are assigned to a specific device terminal 1 and switched according to the property to be tested.

In addition, the insulating support bar 15 that exists in the place of the central axis of the test electrode 5 keeps the physical relationship between the interface board 16 and the fixed part 8 and thereby makes it possible to select an electrode securely and accurately.

### INDUSTRIAL APPLICABILITY

As described above, semiconductor test equipment of the present invention improves the easiness in conducting a test that requires switching of the state of connection between a test unit and a device under test and is therefore useful.

1. (canceled)

2. Semiconductor test equipment comprising:
a test head having a plurality of test electrodes commonly connected to one test unit; and
an interface board having a plurality of board terminals individually connected to a plurality of device terminals of a device under test,
wherein each of the plurality of test electrodes has a movable part so as to come in contact with a corresponding one of the plurality of board terminals and establish an electric connection such that a selective connection path is formed between the test unit and the plurality of device terminals, and
the movable parts of each of the plurality of test electrodes are concentrically arranged.

3. The semiconductor test equipment of claim 2, wherein the interface board has a multilayered structure adapted to the movable parts of each of the plurality of test electrodes.

4. (canceled)

5. Semiconductor test equipment comprising:
a test head having a plurality of test electrodes individually connected to a plurality of test units; and
an interface board having a board terminal electrically connected to one device terminal of a device under test,
wherein each of the plurality of test electrodes has a movable part so as to come in contact with the board terminal and establish an electric connection such that a selective connection path is formed between the plurality of test units and the device terminal, and
the movable parts of each of the plurality of test electrodes are concentrically arranged.

6. The semiconductor test equipment of claim 5, wherein the interface board has a multilayered structure adapted to the movable parts of each of the plurality of test electrodes.
